(19) United States
(12) Patent Application Publication
(10) Pub. No.: US 2024/0341465 A1
(43) Pub. Date: Oct. 17, 2024

(54) BRUSH CLEANING DEVICE AND CHEMICAL MECHANICAL POLISHING APPARATUS

(71) Applicant: SAMSUNG ELECTRONICS CO., LTD., Suwon-si (KR)

(72) Inventors: Jinoh IM, Suwon-si (KR); Seungjiun LEE, Suwon-si (KR); IIyoung YOON, Suwon-si (KR)

(21) Appl. No.: 18/630,000

(22) Filed: Apr. 9, 2024

(30) Foreign Application Priority Data
Apr. 17, 2023 (KR) 10-2023-0049813

(51) Int. Cl. A46B 17/06; A46B 9/00; A46B 9/02; A46B 15/00; B08B 3/10; B08B 5/04; B08B 7/02; H01L 21/67

(52) U.S. Cl. CPC A46B 17/06; A46B 9/005; A46B 9/026; A46B 15/0053; B08B 3/10; B08B 5/04; B08B 7/02; A46B 2200/3073; H01L 21/67046

(57) ABSTRACT

A brush cleaning device includes a brush including an electrode therein; a cleaning tank in which the brush is accommodatable; a platen in the cleaning tank, the platen being spaced apart from the brush, and including an electrode therein that interacts with the electrode of the brush; and a voltage supplier having an electrode interacting with the electrode of the brush, and supplying a voltage to form an electrical field on the brush and the platen, wherein the brush includes a cylindrical body including a plurality of protrusions on a surface thereof, and pores in at least a portion of the plurality of protrusions; a particle collection pipe at a center of the cylindrical body; and a particle suction pipe in fluid communication with the particle collection pipe and extending radially to the pores at an outer surface of the brush.

### CROSS-REFERENCE TO RELATED APPLICATION

This application claims the priority and benefit of Korean Patent Application No. 10-2023-0049813, filed on Apr. 17, 2023, with the Korean Intellectual Property Office, the entire content of which is incorporated herein by reference.

### BACKGROUND

### 1. Field

Embodiments relate to a brush cleaning device and a chemical mechanical polishing apparatus including the same.

### 2. Description of the Related Art

As a manufacturing process of a semiconductor wafer, chemical mechanical polishing may be used for planarization of deposited layers of a semiconductor wafer and a patterning process. Chemical mechanical polishing, and the CMP process, may be performed using a ceria abrasive.

### SUMMARY

The embodiments may be realized by providing a brush cleaning device including a brush including an electrode therein; a cleaning tank in which the brush is accommodatable; a platen in the cleaning tank, the platen being spaced apart from the brush, and including an electrode therein that interacts with the electrode of the brush; and a voltage supplier having an electrode interacting with the electrode of the brush, and supplying a voltage to form an electrical field on the brush and the platen, wherein the brush includes a cylindrical body including a plurality of protrusions on a surface thereof, and pores in at least a portion of the plurality of protrusions; a particle collection pipe at a center of the cylindrical body; and a particle suction pipe in fluid communication with the particle collection pipe and extending radially to the pores at an outer surface of the brush.

The embodiments may be realized by providing a brush cleaning device configured to clean a brush on which particles have been adsorbed after cleaning a wafer, the brush cleaning device including a brush including an electrode; a cleaning tank accommodating the brush and containing a cleaning solution; and a platen in the cleaning tank and spaced apart from the brush, the platen having an electrode therein that generates an attractive force or a repulsive force.

The embodiments may be realized by providing a brush cleaning device for chemical mechanical polishing apparatus cleaning and polishing a surface of a wafer, the brush cleaning comprising: a cleaning tank cleaning a brush on which particles adsorbed; a brush including an electrode disposed on inner side of a surface of the brush; and a platen spaced apart from the brush in the cleaning tank; wherein the platen includes an electrode that interacts with the electrode of the brush, so that an electric field is generated in the brush and the platen, and the brush includes: a cylindrical body including a plurality of protrusions on a surface and having pores in at least a portion of the plurality of protrusions; a particle collection pipe in a center of the cylindrical body; and a particle suction pipe in fluid communication with the particle collection pipe and extending radially to the pores at an outer surface of the brush.

The embodiments may be realized by providing a chemical mechanical polishing apparatus including a polishing chamber including a polishing pad for polishing a surface of a wafer; a wafer cleaning chamber in which the surface of the wafer polished in the polishing chamber is cleaned with a brush; and a brush cleaning chamber for cleaning a brush on which particles have been adsorbed, wherein the brush cleaning chamber further includes a platen having an electrode interacting with an electrode in the brush, and the brush includes a cylindrical body including a plurality of protrusions on a surface and having pores in at least a portion of the plurality of protrusions; a particle collection pipe in a center of the cylindrical body; and a particle suction pipe in fluid communication with the particle collection pipe and extending radially to the pores at an outer surface of the brush.

### BRIEF DESCRIPTION OF DRAWINGS

Features will be apparent to those of skill in the art by describing in detail exemplary embodiments with reference to the attached drawings in which:

FIG. 1 is a schematic diagram of a chemical mechanical polishing apparatus of a semiconductor wafer according to an example of the present disclosure;

FIG. 2 is a schematic diagram of the configuration of a wafer surface cleaning device of the chemical mechanical polishing apparatus of FIG. 1;

FIG. 3 is a longitudinal cross-sectional view of a brush according to an example embodiment;

FIG. 4 is a schematic diagram of a brush cleaning device to which a brush of a first embodiment and a platen of a first embodiment are applied in the cross-section A-A′ of FIG. 3;

FIG. 5 illustrates a brush of a second embodiment of the cross-section A-A′ of FIG. 3;

FIG. 6 illustrates a brush of a third embodiment of the cross-section A-A′ of FIG. 3;

FIG. 7 illustrates a platen of a second embodiment according to an example embodiment;

FIG. 8 illustrates a platen of a third embodiment according to an example embodiment; and

FIG. 9 is a schematic diagram of applying an electrical field to a pair of brushes in the brush cleaning device.

### DETAILED DESCRIPTION

### Chemical Mechanical Polishing Apparatus of Semiconductor Wafer

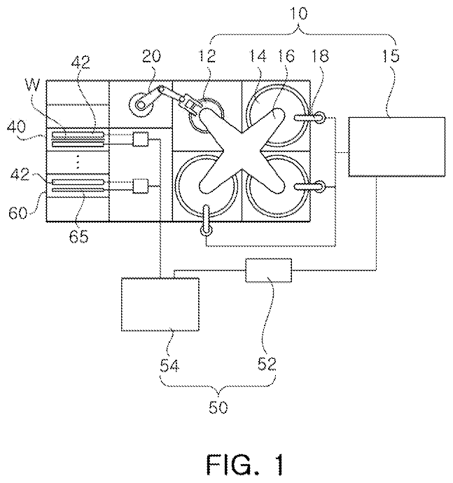

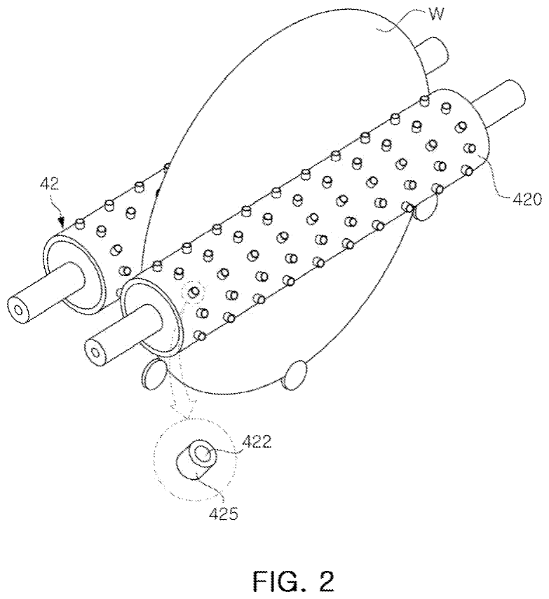

FIG. 1 is a schematic diagram of a chemical mechanical polishing apparatus of a semiconductor wafer according to an example of the present disclosure, and FIG. 2 is a schematic diagram illustrating a configuration of a wafer surface cleaning device of the chemical mechanical polishing apparatus of FIG. 1.

Referring to FIGS. 1 and 2, the chemical mechanical polishing apparatus of the semiconductor wafer may include a polishing chamber 10, a wafer cleaning chamber 40, and a brush cleaning chamber 60.

The polishing chamber 10 may include, e.g., a polishing module for polishing a surface of a wafer W. The polishing module may include, e.g., a rod cup 12, a polishing pad 14, a polishing head 16, a slurry nozzle 18, and a slurry supply 15.

The rod cup 12 may be adjacent to a robot arm 20, and the robot arm 20 may move the polished wafer W on the rod cup 12 to the wafer cleaning chamber 40.

The polishing pad 14 may be adjacent to the rod cup 12 and may polish the wafer W. The polishing pad 14 may include, e.g., a non-woven fabric. The wafer W may be sequentially provided on the plurality of polishing pads 14.

The polishing head 16 may transfer the wafer W between the polishing pad 14 and the rod cup 31. In an implementation, the polishing head 16 may adsorb or hold the wafer W in a vacuum state to transfer the wafer W between the polishing pad 14 and the rod cup 31. In an implementation, the polishing head 16 may rotate the wafer W on the polishing pad 14, and the wafer W and the polishing pad 14 may be polished by friction.

The slurry nozzle 18 may be on a portion of the polishing pad 14, and may be connected to the slurry supply 15. The slurry helps or accelerates polishing of the wafer W, and may be an abrasive for polishing a dielectric thin film (e.g., a silicon oxide or silicon nitride thin film) or a metal thin film (e.g., a copper thin film). In an implementation, the abrasive for the dielectric thin film may include, e.g., silica or ceria. In an implementation, the abrasive for the metal thin film may include, e.g., hydrogen peroxide or ammonia water.

In the wafer cleaning chamber 40, a polished wafer W moved by the robot arm 20 may be cleaned. As illustrated in FIG. 2, in the wafer cleaning chamber 40, the slurry on the polished wafer W may be cleaned using rinsing or an etchant. In an implementation, the wafer W may be between a pair of brushes 42 and brushed.

The brush 42 used in the wafer cleaning chamber 40 may adsorb, hold, or otherwise remove contaminant particles while brushing a surface of the wafer W, and the brush 42 (to which the contaminant particles have been adsorbed) may be moved to the brush cleaning chamber 60 for brush cleaning. The brush cleaning chamber 60 may clean the brush 42 with a brush cleaning device.

A controller 50 of FIG. 1 may control the polishing chamber 10, the wafer cleaning chamber 40, and the brush cleaning chamber 60. A polishing controller 52 may also control opening and closing of the slurry nozzle 18. In an implementation, a plurality of slurries may be used, and the slurry may be independently selected and an amount thereof may be independently adjusted.

In an implementation, a cleaning controller 54 may be connected to the wafer cleaning chamber 40 and the brush cleaning chamber 60 to control use of brushing, rinsing, chemical liquid cleaners, or the like. In an implementation, the cleaning controller 54 may include a voltage supplier, and may apply a voltage to each electrode of the brush 42 and the platen 65 of the brush cleaning chamber 60 to form an electrical field to remove contaminant particles adsorbed on the brush 42.

### Brush Cleaning Device

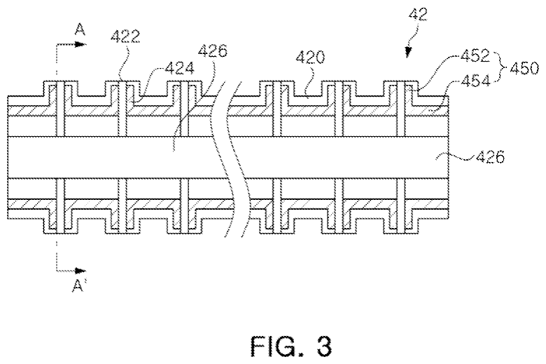

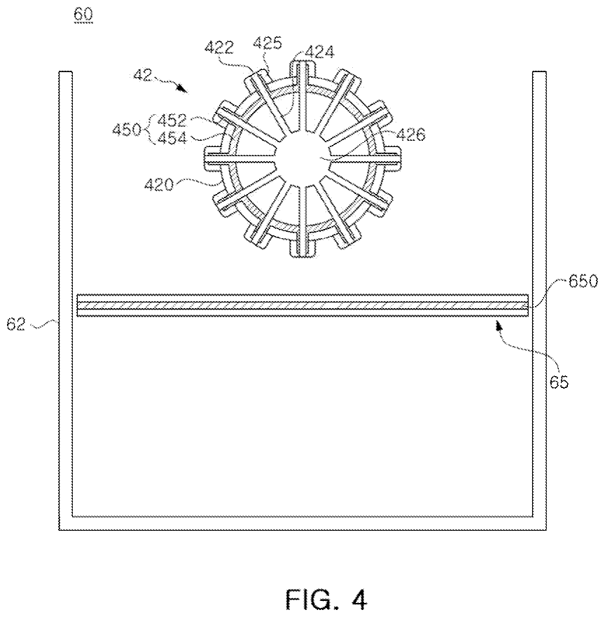

FIG. 3 is a longitudinal cross-sectional view of a brush according to an example embodiment, and FIG. 4 is a schematic diagram of a brush cleaning device to which a brush of a first embodiment and a platen of a first embodiment are applied in the cross-section A-A′ of FIG. 3.

Referring to FIGS. 3 and 4, the brush cleaning device according to an example embodiment may be in a brush cleaning chamber 60. The brush cleaning device may clean a brush 42 (on which particles have been adsorbed after cleaning a wafer W). The brush cleaning device may include a brush 42, a cleaning tank 62, a platen 65, and a voltage supplier.

The brush 42 may include an electrode 450 for cleaning in the brush cleaning device. The brush 42 (on which particles have been adsorbed after cleaning the wafer W) may be accommodated in the cleaning tank 62.

The platen 65 may be spaced apart at a distance from the brush 42 in the cleaning tank 62, and the electrode 650 may be inside the platen 65.

The voltage supplier may supply a voltage to form an electrical field to or at the electrode 450 of the brush 42 and the electrode 650 of the platen 65.

Referring to a brush of the first embodiment illustrated in FIG. 4, the brush 42 may include a cylindrical body 420, a particle collection pipe 426, and a particle suction pipe 424.

The cylindrical body 420 may include a plurality of protrusions 425 on a surface thereof, and may have pores 422 in at least a portion of the plurality of protrusions 425.

In an implementation, the electrode 450 of the brush 42 may include an inner portion 454 on an inner side of the cylindrical body 420, adjacent to an outer circumferential surface of the cylindrical body 420 (e.g., may be on an inner circumferential surface of the cylindrical body 420), and may further include an outer portion 452 extending to or in the protrusion 425.

The particle collection pipe 426 may be in a center of the cylindrical body 420, and the particle suction pipe 424 may be in fluid communication with the particle collection pipe 426 and may extend radially to the pores 422 at the outer surface of the brush 42.

The pores 422 may have a relatively high frequency of adsorbing contaminated particles. In an implementation, an electrical field may be formed between the brush 42 and the platen 65, and the contaminated particles adsorbed on the cylindrical body 420 and the pores 422 may be separated from the brush 42 or may be moved to the particle collection pipe 426 through the particle suction pipe 424.

In an implementation, an attractive force may act on the electrode 450 of the brush 42 in relation to the electrode 650 of the platen 65, and the particles adsorbed on a surface of the brush 42 may be collected in the particle collection pipe 426 via the particle suction pipe 424.

In an implementation, the contaminated particles collected in the particle collection pipe 426 may be electrically discharged externally through or along a longitudinal direction of the particle collection pipe 426.

In an implementation, a repulsive force may act on the electrode 450 of the brush 42 in relation to the electrode 650 of the platen 65, and the particles adsorbed on the surface of the brush 42 may be separated from the brush 42 and moved in a direction of the platen 65. In this case, the particles collected in the platen 65 may be cleaned as well when the cleaning tank 62 is cleaned.

In an implementation, the brush 42 may self-oscillate when a voltage is applied to help separate the particles from the surface of the brush 42.

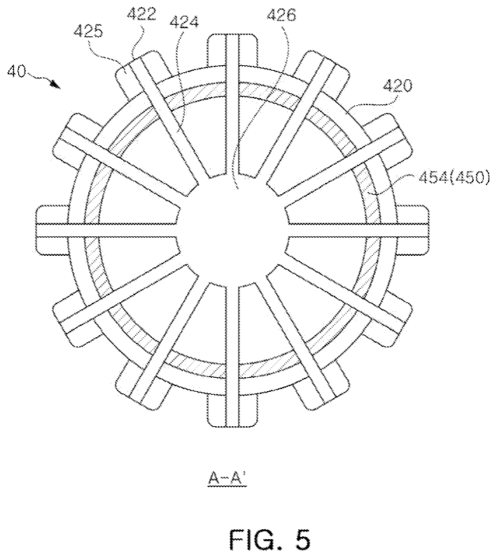

FIG. 5 is a brush of a second embodiment of the cross-section A-A′ of FIG. 3. A brush 42 of the second embodiment is different from the brush of the first embodiment in the disposition of electrodes. An electrode 450 of the brush 42 of the second embodiment may only include the inner portion 454, e.g., may only be on the inner circumferential surface of the cylindrical body 420, and may not include a portion extending on or in the protrusions 425.

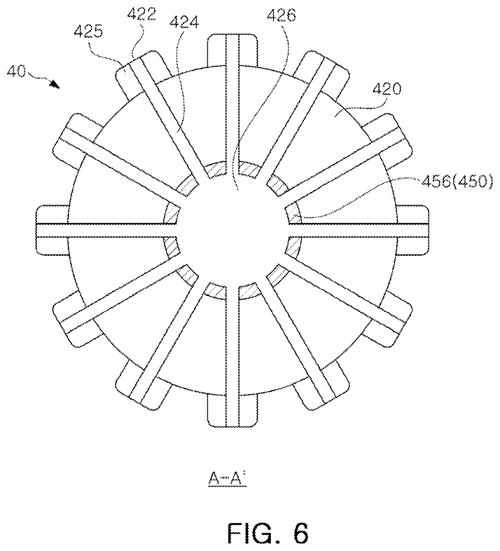

FIG. 6 is a brush of a third embodiment of the cross-section A-A′ of FIG. 3. A brush 42 of the third embodiment is different from the brush of the first embodiment in the disposition of electrodes. An electrode 450 of the brush 42 of the third embodiment may include a portion 456 adjacent to an outer circumferential surface of the particle collection pipe 426.

The electrodes of the brush 42 may be at any or all positions of the electrodes 450 in the first, second and third embodiments.

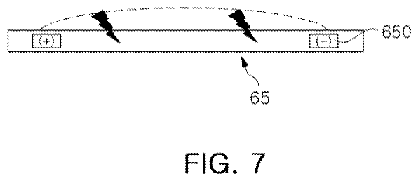

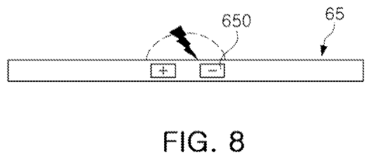

FIG. 7 is a platen of a second embodiment according to an example embodiment, and FIG. 8 is a platen of a third embodiment according to an example embodiment.

An electrode of the platen 65 of the first embodiment illustrated in FIG. 4 may be formed of an electrode 650 of one polarity for an entire platen.

In a second embodiment of FIG. 7, electrodes of different polarities may be at both outer sides of the platen 65. In an implementation, electrodes of the platen 65 of the third embodiment of FIG. 8 may include electrodes of different polarities spaced apart from a center of the platen.

The disposition or arrangement of electrodes of the brush 42 and the platen 65 may be selected with a view toward minimizing damage to a wafer W when the wafer W is cleaned with the brush 42 after considering the size of particles to be removed according to a magnitude of the voltage.

In an implementation, an electrical field may be formed to suit the type or size of the particles by various mechanisms, such as converting a method for applying a voltage from DC to AC.

The embodiment of disposition of electrodes of the brush 42 and the platen 65 of each embodiment may be compatible with each other unless they have a particularly opposite property.

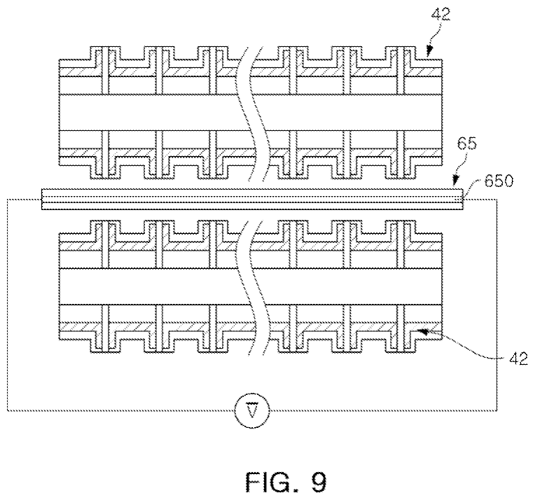

FIG. 9 is a schematic view of applying an electrical field to a pair of brushes in the brush cleaning device of an embodiment.

In the embodiment of FIG. 9, the brush cleaning device may perform self-cleaning by matching a pair of brushes 42 to one platen 65. When the brush is self-cleaned, it may be opposite to the electrical field applied in the wafer (W) cleaning chamber 40.

By way of summation and review, ceria abrasive may use a mechanism of forming a chemical bond with an abrasive film, and it may not be easy to remove particles after the CMP process.

Particles after the CMP process may be slightly etched on a surface of the film using a cleaning solution containing Peracid to remove the particles. Peracid could cause corrosion to a film of a metal, and if a cleaning process were to be performed using a brush for cesium oxide, recontamination, in which cesium oxide adheres to the wafer again, could occur.

Although brush cleaning may effectively remove particles from a surface of a wafer, they could be re-adsorbed, and particle contamination of other wafers could be caused by contaminating particles re-adsorbed on the brush.

As set forth above, according to a brush cleaning device and a chemical mechanical polishing apparatus of the present disclosure, particles re-adsorbed on a brush after chemical mechanical polishing of a wafer may be efficiently removed regardless of the type of abrasive or cleaning solution.

In addition, the particles may be removed through a moving path of contaminated particles in the brush by using an electrical field in the brush, and self-cleaning of the brush itself may be performed.

In addition, re-adsorption into the brush may be prevented while self-cleaning the contaminated brush after the chemical mechanical polishing process in one chemical mechanical polishing apparatus.

One or more embodiments may provide a brush cleaning device to which an electrical field may be applied to efficiently remove particles re-adsorbed on a brush after chemical mechanical polishing of a wafer.

One or more embodiments may provide a brush cleaning device for removing particles by embedding electrodes of various shapes in a brush and a platen, respectively, so as to remove contaminants adsorbed on the brush.

One or more embodiments may provide a chemical mechanical polishing apparatus including a chemical mechanical polishing process chamber and a chemical mechanical polishing post-treatment cleaning process chamber for efficiently removing particles re-adsorbed on a brush.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A brush cleaning device, comprising:
a brush including an electrode therein;
a cleaning tank in which the brush is accommodatable;
a platen in the cleaning tank, the platen being spaced apart from the brush, and including an electrode therein that interacts with the electrode of the brush; and
a voltage supplier having an electrode interacting with the electrode of the brush, and supplying a voltage to form an electrical field on the brush and the platen,
wherein the brush includes:
a cylindrical body including:
a plurality of protrusions on a surface thereof, and
pores in at least a portion of the plurality of protrusions;
a particle collection pipe at a center of the cylindrical body; and
a particle suction pipe in fluid communication with the particle collection pipe and extending radially to the pores at an outer surface of the brush.

2. The brush cleaning device as claimed in claim 1, wherein, when an attractive force acts on the electrode of the brush in relation to the electrode of the platen, particles adsorbed on a surface of the brush are collected in the particle collection pipe via the particle suction pipe.

3. The brush cleaning device as claimed in claim 2, wherein the particles in the particle collection pipe are electrically discharged through the particle collection pipe.

4. The brush cleaning device as claimed in claim 1, wherein, when a repulsive force acts on the electrode of the brush in relation to the electrode of the platen, particles adsorbed on a surface of the brush are separated from the brush and move in a direction toward the platen.

5. The brush cleaning device as claimed in claim 1, wherein, when a voltage is applied, the brush is vibrated to separate particles from the brush.

6. The brush cleaning device as claimed in claim 1, wherein the electrode of the brush is on an inner circumferential surface of the cylindrical body.

7. The brush cleaning device as claimed in claim 6, wherein the electrode of the brush further extends to be adjacent to the plurality of protrusions.

8. The brush cleaning device as claimed in claim 1, wherein the electrode of the brush is on an outer circumferential surface of the particle collection pipe.

9. The brush cleaning device as claimed in claim 1, wherein the electrode of the platen includes an electrode of one polarity of the entire platen, an electrode of another polarity on both outer sides of the platen, or an electrode of another polarity spaced apart from a center of the platen.

10. A brush cleaning device configured to clean a brush on which particles have been adsorbed after cleaning a wafer, the brush cleaning device comprising:
a brush including an electrode;
a cleaning tank accommodating the brush and containing a cleaning solution; and
a platen in the cleaning tank and spaced apart from the brush, the platen having an electrode therein that generates an attractive force or a repulsive force.

11. The brush cleaning device as claimed in claim 10, wherein the brush includes:
a cylindrical body including:
a plurality of protrusions on a surface thereof, and
a plurality of pores in at least a portion of the plurality of protrusions,
a particle collection pipe at a center of the cylindrical body, and
a particle suction pipe in fluid communication with the particle collection pipe and the plurality of pores.

12. The brush cleaning device as claimed in claim 11, wherein, when the attractive force acts on the electrode of the brush in relation to the electrode of the platen, particles adsorbed on a surface of the brush are collected in the particle collection pipe via the particle suction pipe.

13. The brush cleaning device as claimed in claim 11, wherein, when the repulsive force acts on the electrode of the brush in relation to the electrode of the platen, particles adsorbed on a surface of the brush are separated from the brush and move in a direction toward the platen.

14. The brush cleaning device as claimed in claim 11, wherein the electrode of the brush is on an inner circumferential surface of the cylindrical body.

15. The brush cleaning device as claimed in claim 14, wherein the electrode of the brush further extends to be adjacent to the plurality of protrusions.

16. The brush cleaning device as claimed in claim 11, wherein the electrode of the brush is on an outer circumferential surface of the particle collection pipe.

17. The brush cleaning device as claimed in claim 10, wherein the electrode of the platen includes an electrode of one polarity of the entire platen, an electrode of another polarity on both outer sides of the platen, or an electrode of another polarity spaced apart from a center of the platen.

18. A brush cleaning device for chemical mechanical polishing apparatus cleaning and polishing a surface of a wafer, the brush cleaning comprising:
a cleaning tank cleaning a brush on which particles adsorbed;
a brush including an electrode disposed on inner side of a surface of the brush; and
a platen spaced apart from the brush in the cleaning tank;
wherein:
the platen includes an electrode that interacts with the electrode of the brush, so that an electric field is generated in the brush and the platen, and
the brush includes:
a cylindrical body including a plurality of protrusions on a surface and having pores in at least a portion of the plurality of protrusions;
a particle collection pipe in a center of the cylindrical body; and
a particle suction pipe in fluid communication with the particle collection pipe and extending radially to the pores at an outer surface of the brush.

19. The brush cleaning device as claimed in claim 18, wherein, when an attractive force acts on the electrode of the brush in relation to the electrode of the platen, particles adsorbed on a surface of the brush are collected in the particle collection pipe via the particle suction pipe.

20. The brush cleaning device as claimed in claim 18, wherein, when a repulsive force acts on the electrode of the brush in relation to the electrode of the platen, particles adsorbed on the surface of the brush are separated from the brush and move in a direction toward the platen.
